(19) United States
(12) Patent Application Publication
(10) Pub. No.: US 2017/0317245 A1
(43) Pub. Date: Nov. 2, 2017

(54) METHOD OF APPLYING A MATERIAL TO A SURFACE

(71) Applicant: OSRAM Opto Semiconductors GmbH, Regensburg (DE)

(72) Inventors: Björn Hoxhold, Sinzing (DE); Matthias Kiessling, Bad Abbach (DE); Matthias Sperl, Mintraching (DE)

(21) Appl. No.: 15/524,036

(22) PCT Filed: Oct. 16, 2015
(86) PCT No.: PCT/EP2015/074043

§ 371 Date: May 3, 2017

(30) Foreign Application Priority Data
Nov. 4, 2014 (DE) 10 2014 116 076.2

(51) Int. Cl. H01L 33/50; H01L 33/56; H01L 33/60

(52) U.S. Cl. CPC H01L 33/505; H01L 33/60; H01L 33/56; H01L 2933/005; H01L 2933/0058; H01L 2933/0041

(57) ABSTRACT

A method of applying a first material to a surface in a plurality of mutually separate coating regions includes: A) providing the surface containing the coating regions; B) producing a first masking layer on the surface by a photolithographic process, wherein the first masking layer includes a plurality of first openings arranged above the coating regions; C) providing a self-supporting second masking layer and then applying the second masking layer to the first masking layer, wherein the second masking layer includes a plurality of second openings arranged above the first openings and having a size less than or equal to a size of the first openings; and D) applying the first material to the surface in the coating regions through the first and second openings in the first and second masking layers.

### TECHNICAL FIELD

This disclosure relates to a method of applying a material to a surface.

### BACKGROUND

It could be helpful to provide a method of applying a material to a surface in which method masks are used.

### SUMMARY

We provide a method of applying a first material to a surface in a plurality of mutually separate coating regions including:

A) providing the surface containing the coating regions;

B) producing a first masking layer on the surface by a photolithographic process, wherein the first masking layer includes a plurality of first openings arranged above the coating regions;

C) providing a self-supporting second masking layer and then applying the second masking layer to the first masking layer, wherein the second masking layer includes a plurality of second openings arranged above the first openings and having a size less than or equal to a size of the first openings; and

D) applying the first material to the surface in the coating regions through the first and second openings in the first and second masking layers.

### BRIEF DESCRIPTION OF THE DRAWINGS

FIGS. 1 to 9 are schematic diagrams of method steps of a method according to one example.

FIG. 10 shows a method step of a method according to another example.

### DETAILED DESCRIPTION

We provide a method wherein a first material may be applied onto a surface. The surface comprises a plurality of mutually separate coating regions, with the first material being applied to the surface in the plurality of mutually separate coating regions. Those regions of the provided surface that are the regions to which the first material is meant to be applied are referred to as coating regions. Thus, after application, the first material forms on the surface mutually separate regions arranged in the coating regions. The elements formed by the first material can have any shape. For instance, viewed from above towards the surface, the elements formed by the first material can have a square, rectangular, circular, elliptical or other polygonal or round cross section or a combination thereof.

In a first method step, the surface containing the coating regions may be provided. The surface can be entirely flat, for instance. Alternatively, it is also possible that the surface comprises surface structures, for example, structures such as recesses or trenches extending into the surface and arranged beside the coating regions. For instance, a recess and/or a trench can lie between each pair of adjacent coating regions.

To provide the surface containing the coating regions, an interconnected structure of a plurality of electronic semiconductor chips may be provided. The interconnected structure comprises the surface to be coated by the first material. In particular, the coating regions can be surface regions of the semiconductor chips. In particular, it may be an interconnected structure of a plurality of light emitting semiconductor chips. In this case, the coating regions are formed by light outcoupling surfaces of the semiconductor chips or at least portions thereof.

The interconnected structure may be, for example, a wafer containing an epitaxially grown semiconductor layer sequence. This can mean in particular that a growth substrate is provided in the form of a growth substrate wafer on which the semiconductor layer sequence is epitaxially grown. It is also possible to transfer to a carrier wafer a semiconductor layer sequence grown epitaxially on a growth substrate wafer, and remove at least some of the growth substrate wafer, with the result that the carrier wafer together with the applied semiconductor layer sequence can form the interconnected structure. In an interconnected structure of this type, it is possible to provide in a continuous arrangement for the method, electronic semiconductor chips, particularly preferably light emitting semiconductor chips, which can be produced by a later singulation process. In light emitting semiconductor chips, the light outcoupling surfaces are those surface regions via each of which light is emitted during the subsequent operation of the light emitting semiconductor chips.

It is also possible that the interconnected structure is formed by a wafer substitute comprising a plurality of electronic semiconductor chips, preferably of light emitting semiconductor chips held in a frame formed by a molded body. In other words, this means that a plurality of singulated semiconductor chips are provided, around which the molded body is molded in a molding process, and which, together with the molded body, form the interconnected structure. The surface to which the first material is applied can be formed by at least part of a surface of the semiconductor chips and/or by at least part of a surface of the molded body.

After the first material has been applied, the interconnected structure may be divided into a plurality of singulated semiconductor devices, each of which comprises at least one semiconductor chip having a coating made of the first material. In particular when the interconnected structure containing light emitting semiconductor chips is provided, after the first material is applied, the interconnected structure can be divided into a plurality of singulated light emitting semiconductor devices, each of which comprises at least one light emitting semiconductor chip having a coating made of the first material on the light outcoupling surface.

In a further method step, a first masking layer may be produced on the surface by a photolithographic process. This can mean in particular that the first masking layer is formed by a photoresist. This can be done by applying the photoresist over in a large-area fashion on the surface by spin-coating and/or by lamination and/or by spray-coating or another suitable technique. Then the photoresist can be patterned by exposure to light. The photoresist may be a positive or negative photoresist, with the result that by exposure to light in a known manner, development of the photoresist and stripping of portions of the photoresist, a plurality of first openings are formed in the photoresist layer arranged above the coating regions. Once produced, the first masking layer thereby comprises a plurality of first openings arranged above the coating regions and leave the coating regions uncovered, with the shape of the first openings in the first masking layer matching the shape of the elements on the surface formed later by the first material. In particular, the first masking layer can be produced in immediate contact directly on the surface. In other words, this means that a photoresist layer is applied directly over in a large-area fashion on the surface, and then patterned to form the first openings above the coating regions.

The first masking layer may have a thickness greater than the thickness of the first material, which is applied to the surface in the coating regions. Hence, after application, the first material has a thickness that is less than the thickness of the first masking layer.

A self-supporting second masking layer may be provided. The self-supporting second masking layer can also be referred to as a “mechanical mask”. In this context, “self-supporting” means in particular that the second masking layer is not produced on the surface and/or on the first masking layer, but is produced and provided as a separate element independently of the surface and of the first masking layer. The self-supporting second masking layer is then applied to the first masking layer by placing it thereon. In particular, the second masking layer can be applied directly to the first masking layer. The second masking layer comprises a plurality of second openings, which, after the second masking layer has been applied to the first masking layer, are located above the first openings of the first masking layer. In particular, the second openings can be smaller than the first openings. This means that the second openings can have a smaller size, i.e. a smaller cross-sectional area, than the first openings, with the second masking layer in particular covering the edges of the first openings in the first masking layer after the second masking layer has been applied to the first masking layer. In this case, the second openings in the second masking layer can in particular form a circumferential overhang above the first openings in the first masking layer. Particularly preferably, the second openings in the second masking layer have the same cross-sectional shape as the first openings in the first masking layer but are smaller in lateral extent than the openings in the first masking layer. Alternatively, the second openings can also have a different cross-sectional shape from the first openings. In addition, it is also possible that the second openings are the same size as the first openings. This can mean in particular that the cross-sectional areas and cross-sectional shapes of the first and second openings are identical. Thus, the second openings in the second masking layer can have a size that is less than or equal to a size of the first openings. In particular, the second masking layer is applied to the first masking layer such that the material of the first masking layer is entirely covered by the material of the second masking layer, with the result that, viewed from above through the openings in the second masking layer towards the surface containing the masking layers, it is not possible to see the top face of the first masking layer that faces away from the surface.

The second masking layer may comprise a metal or be made of a metal. This can mean in particular that the second masking layer is provided as a self-supporting metal mask containing the second openings. Alternatively, the second masking layer can also be made of another stiff, self-supporting material. In addition, the second masking layer can also be formed by a screen commonly used in screen-printing.

The first material may be applied to the surface in the coating regions through the first and second openings in the first and second masking layers. In particular, a spray-coating process, a printing process or a dispensing process can be used for this purpose, i.e. a process in which a suitable dispensing apparatus is used to introduce the first material into the openings in the masking layer and hence to apply the first material to the surface in the mutually separate coating regions.

The first material may comprise a plastics material. In particular, the plastics material can comprise or be made of silicone. After being applied to the surface, the first material can hence form mutually separate elements made of plastic, particularly preferably mutually separate elements containing silicone. Furthermore, the first material can also comprise other dielectric materials, i.e. electrically insulating materials, and/or materials that can increase the surface reflectivity, for instance materials such as titanium dioxide. Depending on the material of the first material, after being applied, this first material can be cured before or after removal of at least one masking layer or both masking layers.

The first material may comprise a wavelength conversion material contained in the plastics material in powder form for instance. In this case, after being applied to the surface, the first material can form mutually separate wavelength conversion elements comprising the wavelength conversion material in the plastics material. The wavelength conversion material can comprise one or more of the following materials: rare earth garnets and garnets made of alkaline earth metals, for instance YAG:Ce³⁺, nitrides, nitridosilicates, SiONs, SiAlONs, aluminates, oxides, halophosphates, orthosilicates, sulfides, vanadates and chlorosilicates. In addition, the wavelength conversion material can additionally or alternatively comprise an organic material, which can be selected from a group that includes perylenes, benzopyrenes, coumarins, rhodamines and azo dyes. The first material can comprise suitable mixtures and/or combinations of the wavelength conversion materials mentioned.

The second masking layer may be removed after the first material has been applied to the surface. This can be done simply by lifting off the second masking layer because it has a self-supporting design and hence does not need to be removed by a chemical process or other appropriate technique.

In a further method step, the first masking layer may be removed after the first material has been applied to the surface. In particular, the first masking layer can be removed after the second masking layer has been removed. The first masking layer can be removed chemically using suitable solvents, for example. By virtue of the first masking layer being covered by the second masking layer while the first material is applied, it can be achieved that the first masking layer remains uncovered by the first material, with the result that this first masking layer is left bare after the second masking layer has been removed and thus can be removed independently of the first material by a suitable technique. Alternatively, it is also possible that the first masking layer is only partially removed or not removed at all, and at least some of the first masking layer remains on the surface beside the first material.

After the first and second masking layers have been removed, in particular after completely removing the first and second masking layers, a second material may be applied to regions of the surface not covered by the first material. Particularly preferably, the second material can be different from the first material. For instance, the second material can comprise a reflective material such as TiO₂ for instance. For example, the reflective material can be contained in suitable particulate form in a plastics material. The sequence of the applied layers and materials can also be changed. Thus, it is also possible to apply a patterned layer made of reflective material before applying a patterned wavelength conversion layer, where a first masking layer and second masking layer can be used here accordingly.

The method described here may be used to produce light emitting semiconductor devices, each comprising a light emitting semiconductor chip having a coating made of the first material on a light outcoupling surface. The first material in particular can comprise or be made of a wavelength conversion material in a plastics material such as silicone, for example. In the method of producing the light emitting semiconductor devices, an interconnected structure of a plurality of light emitting semiconductor chips in particular is provided that has a surface containing mutually separate coating regions formed by light outcoupling surfaces of the semiconductor chips. The semiconductor chips can exist already singulated in the interconnected structure, which forms a wafer substitute, or can be provided in wafer form still in the form of an epitaxially grown semiconductor layer sequence. As described above, the first masking layer is produced on the surface of the interconnected structure, it being possible in particular to produce the first masking layer directly on the surface of the interconnected structure. Above the structure, the self-supporting second masking layer is applied to the first masking layer, with the second masking layer preferably being arranged in direct contact on the first masking layer. Then the first material is applied through the first and second openings in the first and second masking layers to the surface of the interconnected structure in the mutually separate coating regions, whereby wavelength conversion elements are formed by the first material on the light outcoupling surfaces of the semiconductor chips. The plurality of singulated light emitting semiconductor devices are formed by subsequent singulation of the interconnected structure containing the first material applied in the separate coating regions.

Unlike the method described here, metal masks were previously used to demarcate laterally a mixture made of a wavelength conversion material and a plastic during application by spraying or printing. To dispense such materials, it was necessary for there to be suitable cavities present, formed by undercuts, or to set up suitable barriers. In contrast, using the method described here, it is possible to improve the precision of the lateral demarcation of the deposition of the first material by first fabricating a photo-lithographically produced first masking layer on the surface to be coated. The thickness of the first masking layer is preferably greater than the thickness of the first material applied later. By applying the second masking layer in the form of a self-supporting masking layer to the first masking layer, which is formed by the photoresist, the surface of the first masking layer is protected from the first material during deposition of this material. The first masking layer is designed here such that in terms of dimension the openings are equal to, or preferably slightly larger than, the openings in the subsequently applied second masking layer. This means that material is applied only inside the cavities formed by the first and second openings in the first and second masking layers because the second openings in the second masking layer are the same size as, or preferably smaller than, the first openings in the first masking layer. By protecting the surface of the first masking layer from the first material, the removal of the first masking layer, if required, can be done far more simply, indeed may even be possible for the first time.

Furthermore, undercuts required with conventional metal masks can be avoided. Since the shape and the position of the first material on the surface are defined by the openings in the first masking layer, which can be produced on the surface with high precision by photolithography, the requirements for registration accuracy and the tolerance on mask openings are markedly reduced for the second masking layer. It is merely necessary for the second masking layer to cover the first masking layer entirely. Our method described here can be used to produce mutually separate regions of the first material on the surface more simply, because the required tolerances must be met by the photo-lithographically produced first masking layer and not by the subsequently applied second masking layer, which may be a metal masking layer, for instance.

In light emitting semiconductor devices produced by the method described here, a better color homogeneity with reference to the individual semiconductor devices can thereby be achieved, because the first material in the form of wavelength conversion elements can be applied with high precision to the light outcoupling surfaces of the light emitting semiconductor chips. In addition, a higher device efficiency can be achieved, given that the surface reflectivity of a substrate being used or of the layers applied thereto is low because light scattering at semi-absorptive surfaces can be avoided. Regions between the laterally demarcated coating regions, which are coated by the first material, can be filled with a second material, for instance with a highly reflective material both to increase the surface reflectivity beside the first material and to prevent emissions at very wide angles.

Further advantages and developments appear in the examples described below in connection with the figures.

In each of the examples and figures, the same reference numbers may be used to denote identical, similar or equivalent elements. The elements shown and the relative sizes thereof shall not be considered to be to scale; indeed individual elements such as layers, components, devices and regions, for example, may be shown exaggeratedly large to improve visualization and/or understanding.

A method of applying a first material 5 to a surface 1 in a plurality of mutually separate coating regions 2 is described in conjunction with the following figures. The following description refers purely by way of example to a method of producing a plurality of singulated light emitting semiconductor devices 100, each of which comprises a light emitting semiconductor chip 11 having a coating made of the first material 5, which forms a wavelength conversion element 15, on a light outcoupling surface 12.

FIG. 1 shows a first method step, in which a surface 1 containing mutually separate coating regions 2 is provided. In the example shown, the surface 1 to be coated is in particular a surface of an interconnected structure 10 containing a plurality of light emitting semiconductor chips 11, with the coating regions 2 being formed by light outcoupling surfaces 12 of the semiconductor chips 11. For the sake of clarity, the figure shows only the surface 1 and the elements contained therein.

The interconnected structure 10 may be formed, for example, by a wafer containing an epitaxially grown semiconductor layer sequence. The semiconductor layer sequence in particular comprises an active region for generating light. The semiconductor layer sequence can be grown particularly preferably on a growth substrate by an epitaxy technique, for instance by metalorganic vapor phase epitaxy (MOVPE) or molecular beam epitaxy (MBE). In particular, the growth substrate can be formed by a growth substrate wafer.

The semiconductor layer sequence can be based on different semiconductor material systems depending on the required wavelength to be emitted by the finished semiconductor devices. A semiconductor layer sequence based on InₓGa_{y}Al_{1-x-y}As, for instance, is suitable for a long-wavelength infrared to red emission, a semiconductor layer sequence based on InₓGa_{y}Al_{1-x-y}P, for instance, is suitable for red to yellow radiation, and a semiconductor layer sequence based on InₓG_{ay}Al_{1-x-y}N, for instance, is suitable for short-wavelength visible radiation, i.e. in particular for green to blue radiation, and/or for UV radiation, where 0≦x≦1 and 0≦y≦1 in each case. In addition, a semiconductor layer sequence based on an antimonide, for example, InSb, GaSb, AlSb or a combination thereof, can be suitable for long-wavelength infrared radiation.

The growth substrate can comprise an insulating material or a semiconductor material, for instance an aforementioned compound semiconductor material system. In particular, the growth substrate can comprise or be made of sapphire, GaAs, GaP, GaN, InP, SiC, Si and/or Ge.

The semiconductor layer sequence can be fabricated containing an active region, for example, containing a conventional pn-junction, a double heterostructure, a single quantum well structure (SQW structure) or a multi-quantum well structure (MQW structure). In addition to the active region, the semiconductor layer sequence can include further functional layers and functional regions, for instance n-type or p-type charge carrier transport layers, undoped or p-type or n-type confinement, cladding or waveguide layers, barrier layers, planarization layers, buffer layers, protective layers and/or electrodes, and combinations thereof. The structures described here relating to the active region or to the further functional layers and regions, in particular the design, function and construction thereof, are known and therefore are not described in greater detail here.

The growth process can take place in particular on the uncut wafer, as described above. This is done by providing a growth substrate in the form of a wafer, onto which the semiconductor layer sequence is grown in a large-area fashion. The grown semiconductor layer sequence can be singulated into individual semiconductor chips 11 in a later method step, in which the side faces of the semiconductor chips 11 can be formed by the singulation. In addition, after the growth process, the semiconductor layer sequence can be transferred to a carrier substrate in the form of a carrier substrate wafer, and the growth substrate can be thinned and thereby removed at least in part or entirely. The method steps described below for applying the first material 5 can be carried out on the as yet uncut wafer prior to singulation.

In addition, the interconnected structure 10 can be formed by a wafer substitute containing a plurality of already singulated light emitting semiconductor chips 11 fabricated by the growth process described above and a subsequent singulation process. The light emitting semiconductor chips 11 can be provided in particular in a frame formed by a molded body 13. This means that a plastics material forming a molded body 13 is molded around the light emitting semiconductor chips 11. The figures show purely by way of example a wafer substitute of this type for the purpose of explaining the method. This is intended merely by way of example and has no limiting effect on the method described here. Indeed, the method described here can be carried out also on the uncut wafer in conjunction with an epitaxially grown semiconductor layer sequence, as described above.

The molded body 13 is molded onto the semiconductor chips 11 and encloses the semiconductor chips 11 in a lateral direction, i.e. in a direction along the main extension plane of the light outcoupling surfaces 12 of the semiconductor chips 11. In particular, the molded body 13 can be designed such that the light outcoupling surfaces 12 of the semiconductor chips 11 are not covered. The side faces of the semiconductor chips 11 can be covered entirely or, viewed from a rear face, which is on the opposite side from the light outcoupling surface 12, up to a certain height in the direction of the light outcoupling surface 12, with the result that the molded body 13 can have a top face that is set back from the light outcoupling surfaces 12. Particularly preferably, the side faces of the semiconductor chips 11 can be covered entirely, with the result that the molded body 13 has a top face that is flush with the top faces of the semiconductor chips 11, which surfaces contain the light outcoupling surfaces 12. As shown in the present example, electrical contact regions 14 of the semiconductor chips 11 can also be present in the top face of each chip in addition to the light outcoupling surface 12. Alternatively, for example, the electrical contact regions 14 can be arranged additionally or alternatively also on the rear face of the semiconductor chips 11.

In particular, the molded body 13 can comprise a plastics material, preferably a silicone, an epoxy, a hybrid epoxy-silicone material, a polyester, or a low melting-point glass or a low melting-point glass ceramic. “Low melting-point” denotes those glass materials and glass ceramics that can be processed in a molding process at temperatures that will not damage the semiconductor chips 11. In particular, the molded body 13, as a frame around the semiconductor chips 11, can form an element providing mechanical stability of the wafer substitute forming the interconnected structure 10.

The molded body 13 can be made in particular in a molding process, for instance by injection molding, casting, press-forming, applying a film by lamination or the like. Particularly preferably, the molded body 13 can be formed by a transfer molding process, for instance a film transfer molding process. WO 2011/015449 A1, for instance, describes a method of producing a molded body 13 such as described here, the subject matter of which is incorporated by reference.

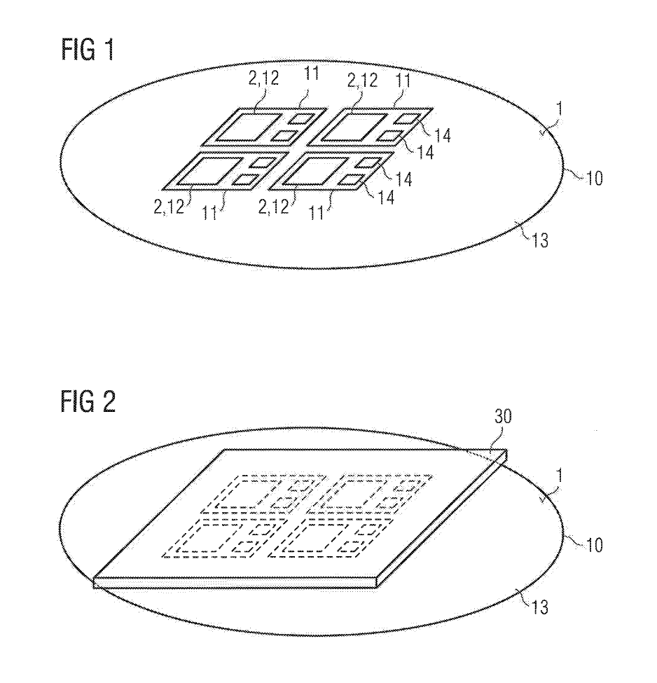

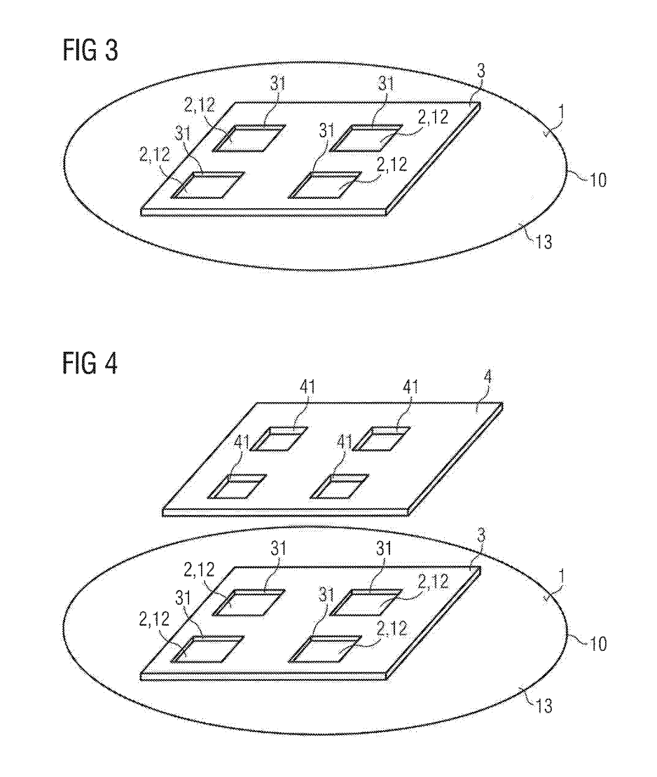

A first masking layer 3 is produced by a photolithographic process on the provided surface 1. As shown in FIG. 2, this is done by applying a photoresist layer 30 over a large area of the provided surface 1. The photoresist layer 30 can be applied, for example, by spin-coating or lamination or spray-coating using a suitable photoresist, in particular a positive or negative resist. First openings 31 in the photoresist layer 30 are formed above the mutually separate coating regions 2, as shown in FIG. 3, by suitable patterning by exposure and development of the photoresist layer 30. This produces the first masking layer 3 containing a plurality of first openings 31, which are arranged above the coating regions 2 of the surface 1 and through which the coating regions 2 are left exposed. The shape of the first openings 31 in this case matches the cross-sectional shape that the first material is meant to have once applied to the coating regions 2.

As shown in FIG. 4, a second masking layer 4, which comprises a plurality of second openings 41, is provided in a further method step. The second masking layer 4 has a self-supporting design and is provided independently and separately from the surface 1 and the first masking layer 3. In particular, the second masking layer 4 may be a masking layer made of a metal. The second masking layer 4 is aligned to arrange the second openings 41 relative to the first openings 31 in the first masking layer 3 such that the second openings 41 cover the first openings. The second masking layer 4 is placed directly on the first masking layer 3 or at least in very close proximity on the first masking layer 3, as shown in FIG. 5.

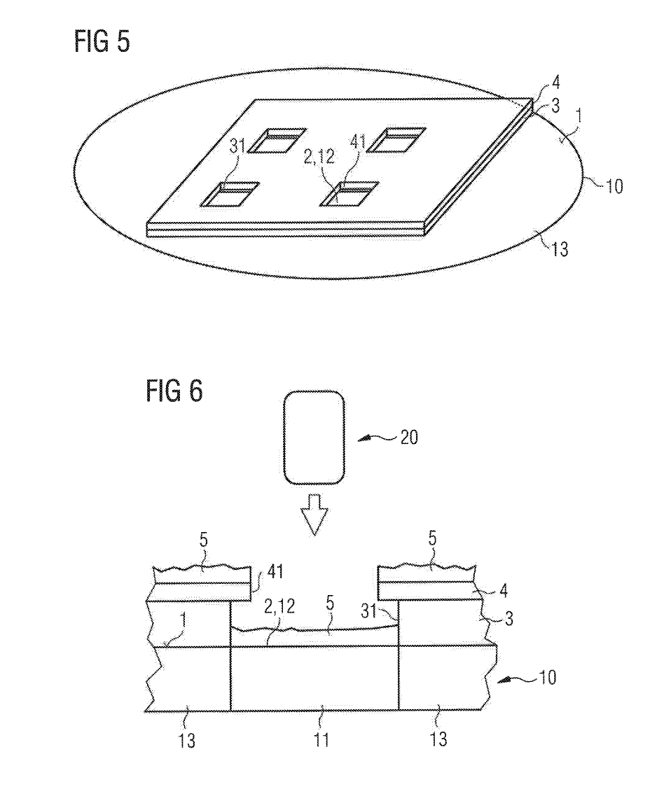

The second openings 41 can be the same size as the first openings 31. Particularly preferably, the second openings 41 can be smaller in size than the first openings 31, as illustrated in the example shown. By virtue of the second openings 41 in the second masking layer 4 being smaller than the first openings 31 in the first masking layer 3, the second openings 41 in the second masking layer 4 form a circumferential overhang above the first openings 31 in the first masking layer 3. The first masking layer 3 is thereby fully covered by the second masking layer 4. Since the shape of the first material 5 to be applied is defined by the cross-sectional shape of the first openings 31 in the first masking layer 3, very low requirements can be set for the registration precision of the second masking layer 4 provided the second masking layer 4 completely covers the first masking layer 3 and no region of the top face of the first masking layer 3 is left exposed through a second opening 41 in the second masking layer 4. This is illustrated in FIG. 6, which shows in a schematic cross-sectional view a detail of the interconnected structure 10 having the masking layers 3, 4 arranged thereon.

In a further method step, as also shown in FIG. 6, a suitable application process 20, in particular a spray-coating process, a printing process or a suitable dispensing process, is used to apply the first material 5 to the surface 1 in the coating regions 2 through the first and second openings 31, 41 in the first and second masking layers 3, 4. It may happen as a result of the application process that the first material 5 is not only applied to the surface 1 in the coating regions 2 but the first material 5 is also deposited on the second masking layer 4.

In the example shown, the first material 5 comprises in particular a plastics material, particularly preferably silicone, containing a wavelength conversion material. The wavelength conversion material is suitable in particular for absorbing at least some of the light generated during operation in the light emitting semiconductor chips 11 and converting the light into light of a different wavelength. The wavelength conversion material in particular may be contained in the plastics material in powder form.

As FIG. 6 also shows, the first material 5 is applied to the surface 1 in the coating regions 2 to a thickness that is less than a thickness of the first masking layer 3, with the result that the first masking layer 3 extends beyond the applied first material 5. The cavities formed by the first and second openings 31, 41 in the first and second masking layers 3, 4 allow precise positioning of the first material 5 on the required coating regions 2.

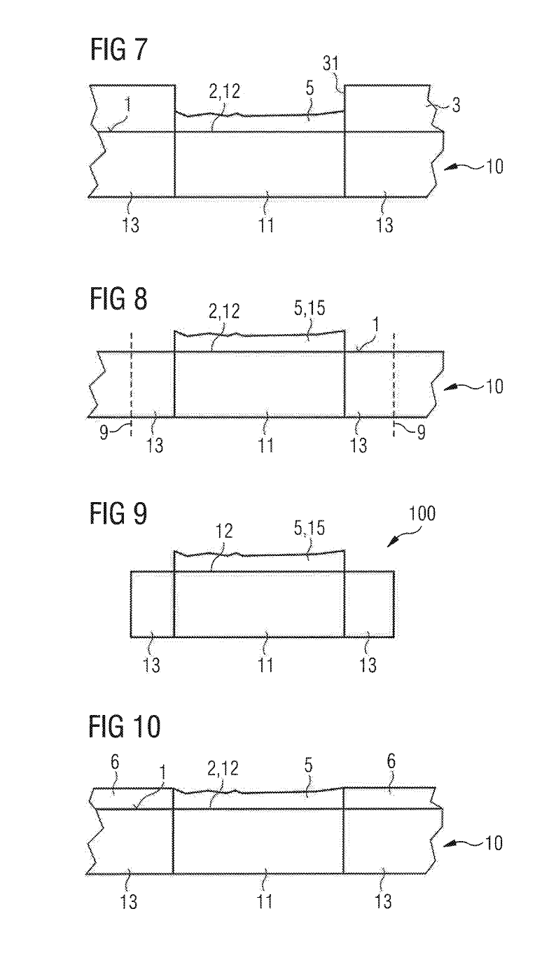

As shown in FIG. 7, the second masking layer 4 is removed in a further method step by lifting off. By virtue of the second masking layer 4 entirely covering the first masking layer 3 while the first material 5 is applied, excess first material 5 that has been applied beside the coating regions 2 is easily removed along with the second masking layer 4 by removal of the layer, with the result that the first masking layer 3 is not covered by the first material 5 after the second masking layer 4 has been removed. The first material 5 thus remains only in the first openings 31 in the first masking layer 3. It is thereby easily possible, for instance using suitable solvents, to remove the first masking layer 3 and hence leave only the first material 5 on the coating regions, as shown in FIG. 8.

In the wavelength conversion material described here in the first material 5, the remaining first material 5 forms wavelength conversion elements 15 on the semiconductor chips 11 in the form of CLC elements (CLC: “Chip Level Conversion”). As an alternative to removing the first masking layer 3 completely, some or even all of the layer can also be left on the surface 1.

In a further method step, the interconnected structure is singulated by dividing up the molded body 13, as indicated by the dashed singulation lines 9 in FIG. 8, thereby producing a plurality of light emitting semiconductor devices 100 comprising a light emitting semiconductor chip 11 and a coating made of the first material 5 in the form of a wavelength conversion element 15 on the light outcoupling surface 12 as shown in FIG. 9.

In addition, it is also possible to coat with a second material 6 regions of the surface 1 which are not covered by the first material 5 after removal of the first and second masking layers 3, 4 as shown in FIG. 10. In particular, the second material 6 can be different from the first material 5 and, for instance when light emitting devices are to be produced, can comprise or be made of a reflective material such as for instance, TiO₂ particles in a plastic. This can increase the surface reflectivity beside the first material 5 and prevent emissions at very wide angles during operation of the light emitting semiconductor device.

The method steps described in conjunction with the figures can additionally or alternatively comprise further features according to the examples described above in the general part.

The description based on the examples has no limiting effect on this disclosure. Instead, the disclosure includes every novel feature and every combination of features, which in particular includes every combination of features in the appended claims, even if the feature or combination is not itself explicitly mentioned in the claims or examples.

This application claims priority of DE 10 2014 116 076.2, the subject matter of which is incorporated herein by reference.

1.-19. (canceled)

20. A method of applying a first material to a surface in a plurality of mutually separate coating regions comprising:
A) providing the surface containing the coating regions;
B) producing a first masking layer on the surface by a photolithographic process, wherein the first masking layer comprises a plurality of first openings arranged above the coating regions;
C) providing a self-supporting second masking layer and then applying the second masking layer to the first masking layer, wherein the second masking layer comprises a plurality of second openings arranged above the first openings and having a size less than or equal to a size of the first openings; and
D) applying the first material to the surface in the coating regions through the first and second openings in the first and second masking layers.

21. The method as claimed in claim 20, wherein the second openings are smaller than the first openings.

22. The method as claimed in claim 21, wherein the second openings in the second masking layer form a circumferential overhang above the first openings in the first masking layer.

23. The method as claimed in claim 20, wherein step B comprises:
B1) applying a photoresist layer in a large area on the surface;
B2) patterning the photoresist layer to form the first openings above the coating regions.

24. The method as claimed in claim 20, wherein the second masking layer is made of a metal.

25. The method as claimed in claim 20, wherein the first material is applied by a spray-coating process, a printing process or a dispensing process.

26. The method as claimed in claim 20, wherein, after application, the first material has a thickness less than a thickness of the first masking layer.

27. The method as claimed in claim 20, wherein the first material comprises a plastics material.

28. The method as claimed in claim 27, wherein the plastics material comprises silicone.

29. The method as claimed in claim 20, wherein the first material comprises a wavelength conversion material.

30. The method as claimed in claim 20, wherein the second masking layer is removed after step D.

31. The method as claimed in claim 30, wherein the first masking layer is removed after step D.

32. The method as claimed in claim 31, wherein, after removal of the masking layers, a second material different from the first material is applied to regions of the surface not covered by the first material.

33. The method as claimed in claim 32, wherein the second material comprises a reflective material.

34. The method as claimed in claim 33, wherein the reflective material comprises TiO₂ particles.

35. The method as claimed in claim 20, wherein, in step A, an interconnected structure of a plurality of light emitting semiconductor chips is provided, and the coating regions are formed by light outcoupling surfaces of the semiconductor chips.

36. The method as claimed in claim 35, wherein the interconnected structure is formed by a wafer containing an epitaxially grown semiconductor layer sequence.

37. The method as claimed in claim 35, wherein the interconnected structure is formed by a wafer substitute containing the plurality of light emitting semiconductor chips in a frame formed by a molded body.

38. The method as claimed in claim 35, wherein, after the first material is applied, the interconnected structure is divided into a plurality of singulated light emitting semiconductor devices, each of which comprises at least one light emitting semiconductor chip having a coating made of the first material on the light outcoupling surface.
